(19) United States
(12) Patent Application Publication
(10) Pub. No.: US 2024/0260385 A1
(43) Pub. Date: Aug. 1, 2024

(54) DISPLAY APPARATUS

(71) Applicant: LG DISPLAY CO., LTD., Seoul (KR)

(72) Inventors: YoungIn JANG, Seoul (KR); KwangSu LIM, Seoul (KR); Soyoung LEE, Seoul (KR); HyunGon KIM, Seoul (KR)

(73) Assignee: LG DISPLAY CO., LTD., Seoul (KR)

(21) Appl. No.: 18/412,402

(22) Filed: Jan. 12, 2024

(30) Foreign Application Priority Data
Jan. 30, 2023 (KR) 10-2023-0011619

(51) Int. Cl. H10K 59/70; H10K 59/122

(52) U.S. Cl. CPC H10K 59/70; H10K 59/122

(57) ABSTRACT

A display apparatus includes a substrate including a first display area and a second display area surrounding the first display area, a plurality of first sub-pixels disposed at the first display area, a plurality of second sub-pixels disposed at the second display area, a first light emitting element disposed at each of the plurality of first sub-pixels, and a second light emitting element disposed at each of the plurality of second sub-pixels. The first light emitting element includes an organic light emitting diode and the second light emitting element includes an inorganic light emitting diode.

### CROSS-REFERENCE TO RELATED APPLICATION

This application claims the priority of Korean Patent Application No. 10-2023-0011619 filed on Jan. 30, 2023, which is hereby incorporated by reference in its entirety.

### BACKGROUND

### Field of the Disclosure

The present disclosure relates to a display apparatus, and more particularly, to a display apparatus using an organic light emitting diode (OLED) and a light emitting diode (LED).

### Description of the Background

As display apparatuses which are used for a monitor of a computer, a television, a cellular phone, or the like, there are an organic light emitting display (OLED) apparatus which is a self-emitting device, a liquid crystal display (LCD) apparatus which requires a separate light source, and the like.

The organic light emitting display (OLED) apparatus is a self-emitting display apparatus so that a separate light source is not necessary, unlike the liquid crystal display (LCD) apparatus. Therefore, the organic light emitting display apparatus may be manufactured to have light weight and thin thickness. Further, since the organic light emitting display apparatus is driven at a low voltage, it is advantageous not only in terms of power consumption, but also in terms of a color reproduction, a response speed, a viewing angle, and a contrast ratio. Therefore, the organic light emitting display apparatus is being studied as next generation displays.

### SUMMARY

However, the organic light emitting display apparatus uses an organic material as an emission layer so that it is very vulnerable to oxygen, moisture, or the like. Accordingly, to minimize the permeation of oxygen and moisture into the organic emission layer from the outside, various techniques are used to seal the organic light emitting diode to form a minimum bezel area to ensure the moisture permeation suppressing reliability. However, the display apparatus was required to be slimmer and thinner, an attempt was made to reduce the bezel area, but there is a limit to reducing the bezel area due to the degradation of the moisture permeation reliability.

Accordingly, the present disclosure is to provide to a display apparatus that substantially obviates one or more of the problems due to limitations and disadvantages described above.

More specifically, the present disclosure is to provide a display apparatus which improves a moisture permeation reliability while minimizing the bezel area.

The present disclosure is also to provide a display apparatus in which an organic emission layer formed on a front surface of a substrate emits light only in a first display area.

Further, the present disclosure is to provide a display apparatus which drives different types of light emitting diodes together.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other advantages and aspects of the present disclosure, as embodied and broadly described herein, a display apparatus includes a substrate including a first display area and a second display area surrounding the first display area, a plurality of first sub-pixels disposed at the first display area, a plurality of second sub-pixels disposed at the second display area, a first light emitting element disposed at each of the plurality of first sub-pixels, and a second light emitting element disposed at each of the plurality of second sub-pixels. The first light emitting element includes an organic light emitting diode and the second light emitting element includes an inorganic light emitting diode. Accordingly, the inorganic light emitting diode is disposed in the second display area which encloses the first display area to protect the organic light emitting diode in the first display area from moisture and oxygen.

According to an aspect of the present disclosure, an inorganic light emitting diode is disposed at an outer peripheral area of a display panel with a low moisture permeation reliability and an organic light emitting diode is disposed in an inner area of the display panel to protect the organic light emitting diode from the moisture and the oxygen.

According to an aspect of the present disclosure, a plurality of dams is minimized in the outer peripheral area of the display panel, but a plurality of inorganic light emitting diodes is formed instead to minimize the permeation of the moisture and oxygen to the organic light emitting diode.

According to an aspect of the present disclosure, an organic emission layer formed on the front surface of the substrate may emit light only in a first display area.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure inventive concepts as claimed.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain principles of the disclosure.

In the drawings:

FIG. 1 illustrates a display apparatus according to an exemplary aspect of the present disclosure;

FIG. 2A is a partial cross-sectional view of a display apparatus according to an exemplary aspect of the present disclosure;

FIG. 2B is a perspective view of a tiling display apparatus according to an exemplary aspect of the present disclosure;

FIG. 3 is a schematic plan view of a display panel of a display apparatus according to an exemplary aspect of the present disclosure;

FIG. 4 is an enlarged plan view of area A of FIG. 3;

FIG. 5A is a circuit diagram of a first sub pixel of a display apparatus according to an exemplary aspect of the present disclosure;

FIG. 5B is a circuit diagram of a second sub pixel of a display apparatus according to an exemplary aspect of the present disclosure;

FIG. 6 is a cross-sectional view of a display apparatus according to an exemplary aspect of the present disclosure.

FIG. 7 is an enlarged plan view of a second pixel according to an exemplary aspect of the present disclosure.

FIG. 8 is a circuit diagram of an electrostatic discharge circuit of a display apparatus according to an exemplary aspect of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Reference is now made in detail to aspects of the present disclosure, examples of which may be illustrated in the accompanying drawings. In the following description, when a detailed description of well-known functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure and implementation methods thereof, are clarified through the exemplary aspects described with reference to the accompanying drawings. The present disclosure may however, be embodied in different forms and should not be construed as limited to the aspects set forth herein. Rather, these exemplary aspects are examples and are provided so that this disclosure may be thorough and complete, to assist those skill in the art to understand the inventive concepts without limiting the protected scope of the present disclosure.

Shapes (e.g., sizes, lengths, widths, heights, thicknesses, locations, radii, diameters, and areas), angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise, ” “have, ” “include, ” “contain, ” “constitute, ” “made up of, ” “formed of, ” or the like is used with respect to one or more elements, one or more other elements may be added unless a term such as “only” or the like is used. The terms used in the present disclosure are merely used to describe example aspects, and are not intended to limit the scope of the present disclosure. The terms of a singular form may include plural forms unless the context clearly indicates otherwise.

The word “exemplary” is used to mean serving as an example or illustration. Aspects are example aspects. “Aspects, ” “examples, ” “aspects, ” and the like should not be construed as preferred or advantageous over other implementations. An aspect, an example, an example aspect, an aspect, or the like may refer to one or more aspects, one or more examples, one or more example aspects, one or more aspects, or the like, unless stated otherwise. Further, the term “may” encompass all the meanings of the term “can. ”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, where the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more parts may be located between two other parts unless a more limiting term, such as “immediate(ly),” “direct(ly),” or “close(ly),” is used. For example, when a structure is described as being positioned “on,” “upon,” “on top of,” “over,” “under,” “above,” “below,” “beneath,” “near,” “close to,” “adjacent to,” “beside,” or “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, may be used to describe a correlation between various elements (e. g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, may include all directions of “above” and “below.” Likewise, an exemplary term “above” or “on” may include both directions of “above” and “below.”

In describing a temporal relationship when the temporal order is described as “after,” “subsequent,” “next,” “before,” “preceding,” “prior to,” or the like a case which is not consecutive or not sequential may be included and thus one or more other events may occur therebetween, unless a more limiting term, such as “just,” “immediate(ly),” or “direct(ly)” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first,” “second,” or the like may be used herein to describe various elements (e.g., layers, films, regions, components, sections, or the like), these elements should not be limited by these terms. These terms are used only to partition one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and may be meant as lines or directions having wider directivities within the range within which the components of the present disclosure may operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure may operate functionally.

The term “at least one” should be understood as including any and all combinations of one or more of the associated listed items. For example, each of the phrases of “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); or some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various aspects of the present disclosure may be partially or entirety coupled to or combined with each other, may be technically associated with each other, and may be variously inter-operated, linked or driven together. The aspects of the present disclosure may be implemented or carried out independently of each other, or may be implemented or carried out together in a co-dependent or related relationship. In one or more aspects, the components of each apparatus according to various aspects of the present disclosure are operatively coupled and configured.

Unless otherwise defined, all terms (including technical and scientific terms) used herein have the same meaning as commonly understood by one of ordinary skill in the art to example aspects belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating aspects.

Further, in a specific case, a term may be arbitrarily selected by the applicant, and in this case, the detailed meaning thereof will be described in a corresponding description herein. Therefore, the terms used herein should be understood based on not only the name of the terms, but also the meaning of the terms and the content hereof.

Hereinafter, a display apparatus according to exemplary aspects of the present disclosure will be described in detail with reference to accompanying drawings.

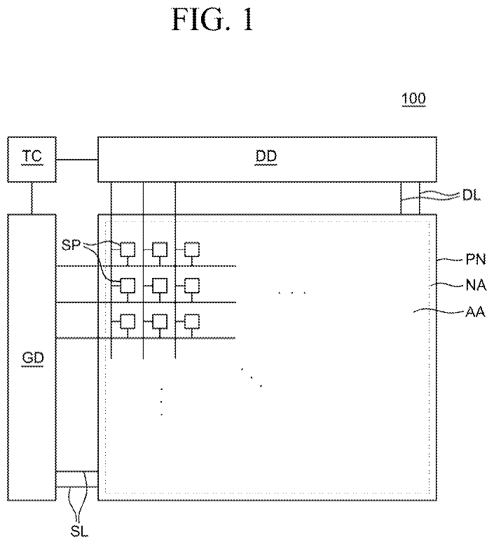

FIG. 1 illustrates a display apparatus according to an exemplary aspect of the present disclosure. In FIG. 1, for the convenience of description, among various components of the display apparatus 100, only a display panel PN, a gate driver GD, a data driver DD, and a timing controller TC are illustrated.

Referring to FIG. 1, the display apparatus 100 includes a display panel PN including a plurality of sub-pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL in accordance with a plurality of gate control signals supplied from the timing controller TC. Even though in FIG. 1, it is illustrated that one gate driver GD is disposed to be spaced apart from one side (or one portion) of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub-pixels SP. In the display panel PN, the plurality of scan lines SL and the plurality of data lines DL intersect each other. The plurality of sub-pixels SP is connected to the scan lines SL and the data lines DL, respectively. In addition, even though it is not illustrated in the drawing, each of the plurality of sub-pixels SP may be connected to a high potential power line, a low potential power line, a reference line, and the like.

In the display panel PN, a display area AA and the non-display area NA enclosing (or surrounding) the display area AA may be defined.

The display area AA is an area in which images are displayed in the display apparatus 100. In the display area AA, a plurality of sub-pixels SP which configures a plurality of pixels PX and a circuit for driving the plurality of sub-pixels SP may be disposed. The plurality of sub-pixels SP is a minimum unit which configures the display area AA and n sub-pixels SP may form one pixel. In each of the plurality of sub-pixels SP, a light emitting diode, a thin film transistor for driving the light emitting diode, and the like may be disposed.

In the display area AA, a plurality of signal lines which transmits various signals to the plurality of sub-pixels SP is disposed. For example, the plurality of signal lines may include a plurality of data lines DL which supplies a data voltage to each of the plurality of sub-pixels SP, a plurality of scan lines SL which supplies a scan signal to each of the plurality of sub-pixels SP, and the like. The plurality of scan lines SL extends in one direction in the display area AA to be connected to the plurality of sub-pixels SP and the plurality of data lines DL extends in a direction different from the one direction in the display area AA to be connected to the plurality of sub-pixels SP. In addition, in the display area AA, a low potential power line, a high potential power line, and the like may be further disposed, but aspects of the present disclosure are not limited thereto.

The non-display area NA is an area where images are not displayed so that the non-display area NA may be defined as an area extending from the display area AA. In the non-display area NA, a link line which transmits a signal to the sub pixel SP of the display area AA, a pad electrode, a driving IC, such as a gate driver IC or a data driver IC, or the like, may be disposed. The non-display area NA may be located on a rear surface of the display panel PN, for example, a surface on which the sub-pixels SP are not disposed or may be omitted, and is not limited as illustrated in the drawing.

A driver, such as a gate driver GD, a data driver DD, and a timing controller TC, may be connected to the display panel PN in various ways. For example, the gate driver GD may be mounted in the non-display area NA in a gate in panel (GIP) manner or mounted between the plurality of sub-pixels SP in the display area AA in a gate in display area (or active area) (GIA) manner. For example, the data driver DD and the timing controller TC are formed in separate flexible film and printed circuit board and may be electrically connected to the display panel PN by bonding (or attaching) the flexible film and the printed circuit board to a pad electrode formed in the non-display area NA of the display panel PN. If the gate driver GD is mounted in the GIP manner and the data driver DD and the timing controller TC transmit a signal to the display panel PN through a pad electrode of the non-display area NA, an area of the non-display area NA to dispose the gate driver GD and the pad electrode needs to be ensured. Thus, a bezel area may be increased.

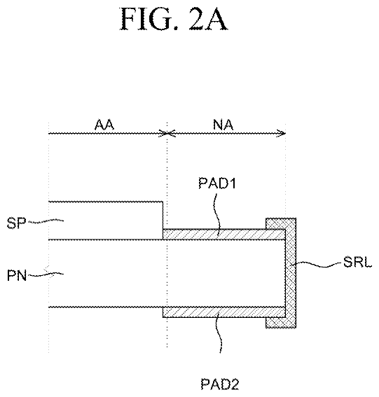

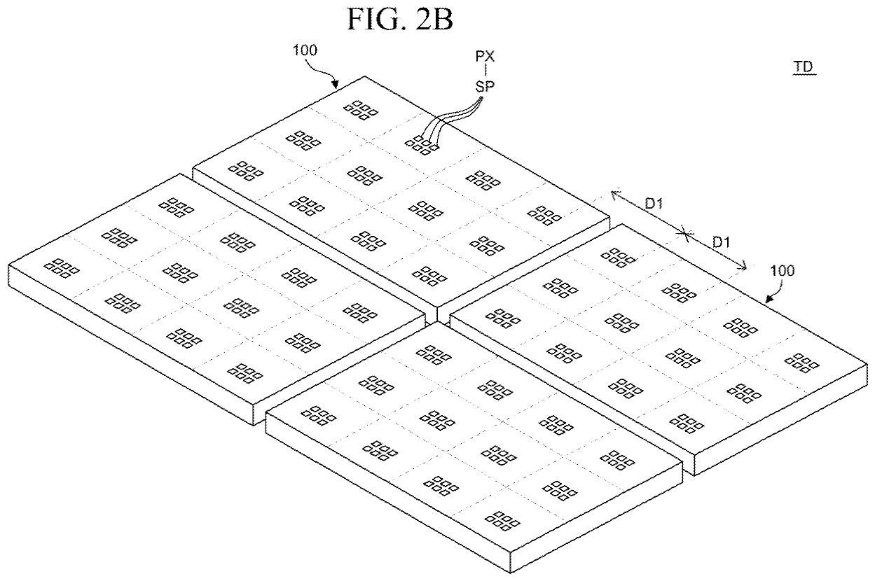

In contrast, when the gate driver GD is mounted in the display area AA in the GIA manner and a side line SRL which connects the signal line on the front surface of the display panel PN to the pad electrode on a rear surface of the display panel PN is formed to bond (or attach) the flexible film and the printed circuit board onto a rear surface of the display panel PN, the non-display area NA may be minimized on the front surface of the display panel PN. Thus, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display apparatus 100 according to an exemplary aspect of the present disclosure. FIG. 2B is a perspective view of a tiling display apparatus TD according to an exemplary aspect of the present disclosure.

In the non-display area NA of the display panel PN, a plurality of pad electrodes for transmitting various signals to the plurality of sub-pixels SP is disposed. For example, in the non-display area NA on the front surface of the display panel PN, a first pad electrode PAD1 which transmits a signal to the plurality of sub-pixels SP is disposed. In the non-display area NA on the rear surface of the display panel PN, a second pad electrode PAD2 which is electrically connected to a driving component, such as a flexible film and the printed circuit board, is disposed.

In this case, various signal lines connected to the plurality of sub-pixels SP, for example, a scan line SL, a data line DL, or the like extend from the display area AA to the non-display area NA to be electrically connected to the first pad electrode PAD1.

The side line SRL is disposed along a side surface of the display panel PN. The side line SRL may be electrically connected to a first pad electrode PAD1 on the front surface of the display panel PN and a second pad electrode PAD2 on the rear surface of the display panel PN. Therefore, a signal from a driving component on the rear surface of the display panel PN may be transmitted to the plurality of sub-pixels SP through (or by) the second pad electrode PAD2, the side line SRL, and the first pad electrode PAD1. Accordingly, a signal transmitting path from the front surface of the display panel PN to the side surface and the rear surface is formed to minimize an area of the non-display area NA of the display panel PN.

Referring to FIG. 2B, a tiling display apparatus TD having a large screen size may be implemented by connecting a plurality of display apparatuss 100. As illustrated in FIG. 2A, when the tiling display apparatus TD is implemented using a display apparatus 100 with a minimized bezel area, a seam area in which an image between the display apparatuses 100 is not displayed is minimized so that a display quality may be improved.

For example, the plurality of sub-pixels SP may form one pixel PX and a distance D1 between an outermost pixel PX of one display apparatus 100 and an outermost pixel PX of another display apparatus 100 adjacent to one display apparatus may be implemented to be equal to a distance D1 between pixels PX in one display apparatus 100. Accordingly, the distance between pixels PX between the display apparatuses 100 is constantly configured to minimize the seam area.

However, FIGS. 2A and 2B are illustrative so that the display apparatus 100 according to the exemplary aspect of the present disclosure may be a general display apparatus 100 with a bezel, but aspects of the present disclosure are not limited thereto.

Hereinafter, the description will be made by assuming that the display apparatus 100 is a zero-bezel display apparatus 100 in which only a display area AA is substantially present on a front surface of the display panel PN.

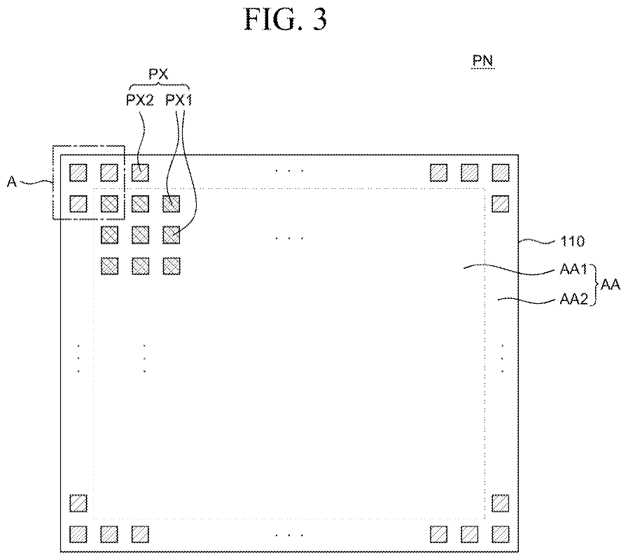

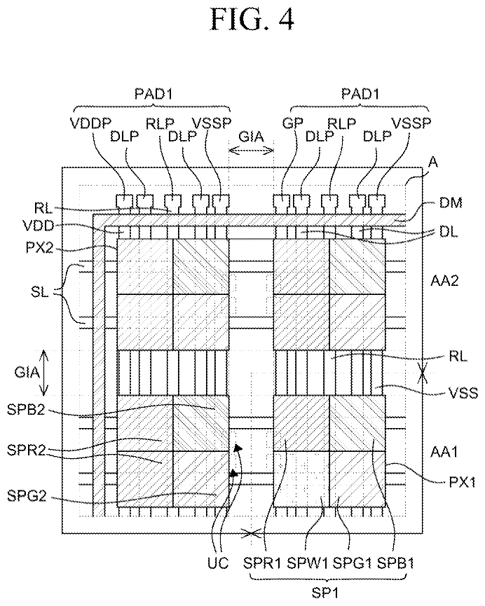

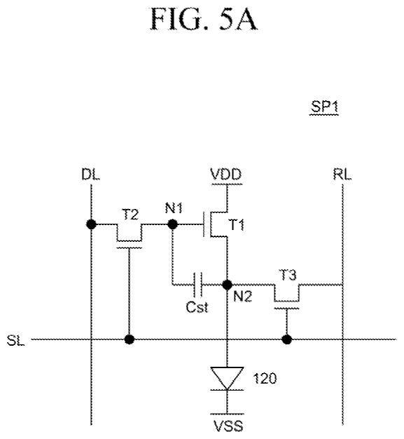

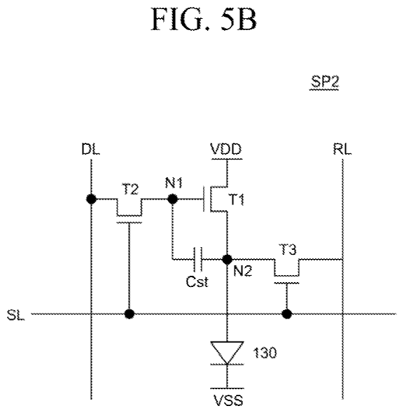

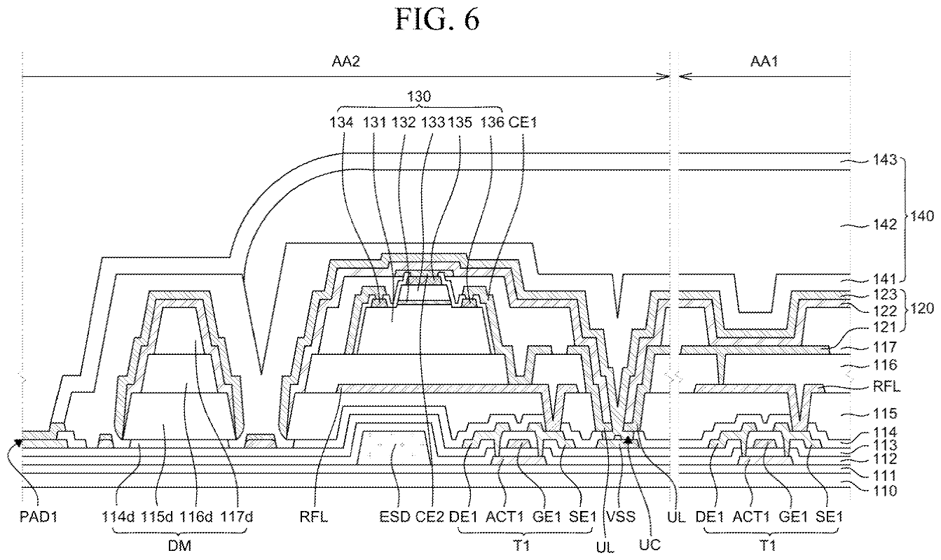

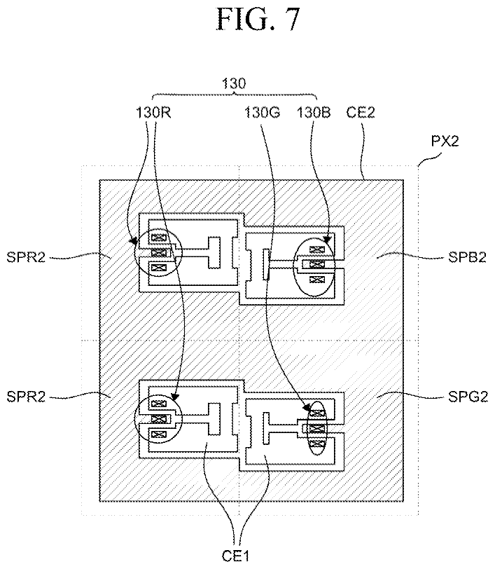

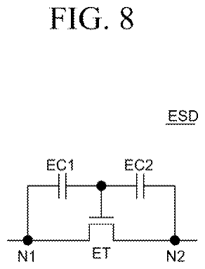

FIG. 3 is a schematic plan view of a display panel of a display apparatus according to an exemplary aspect of the present disclosure. FIG. 4 is an enlarged plan view of an area A of FIG. 3. FIG. 5A is a circuit diagram of a first sub pixel of a display apparatus according to an exemplary aspect of the present disclosure. FIG. 5B is a circuit diagram of a second sub pixel of a display apparatus according to an exemplary aspect of the present disclosure. FIG. 6 is a cross-sectional view of a display apparatus according to an exemplary aspect of the present disclosure. FIG. 7 is an enlarged plan view of a second pixel according to an exemplary aspect of the present disclosure. FIG. 8 is a circuit diagram of an electrostatic discharge circuit of a display apparatus according to an exemplary aspect of the present disclosure. For example, FIG. 6 is a cross-sectional view of a first sub-pixel SP1 of a first display area AA1 and a second sub-pixel SP2 of a second display area AA2.

First, referring to FIGS. 3 and 4, the display panel PN includes a plurality of pixels PX which is formed by a plurality of sub-pixels SP, respectively. Each of the plurality of sub-pixels SP includes a light emitting element and a pixel circuit to independently emit light.

The plurality of pixels PX includes a plurality of first sub-pixels PX1 disposed in the first display area AA1 and a plurality of second sub-pixels PX2 disposed in the second display area AA2. The plurality of first pixels PX1 and the plurality of second pixels PX2 may include different types of light emitting elements. For example, the plurality of first pixels PX1 may include a first light emitting element 120 which is an organic light emitting diode (OLED) and the plurality of second pixels PX2 may include a second light emitting element 130 which is an inorganic light emitting diode (LED).

The first display area AA1 in which the plurality of first pixels PX1 is disposed may be a center display area AA of the display area AA. The first display area AA1 may occupy the most of the display area AA. The second display area AA2 in which the plurality of second pixels PX2 is disposed may be an outer peripheral display area AA of the display area AA. The second display area AA2 may be configured to enclose an entire first display area AA1. In the second display area AA2 having a low moisture permeation reliability, the second pixel PX2 including an inorganic light emitting diode is disposed to reduce the permeation of moisture and oxygen to the first display area AA1, which will be described below in more detail. However, aspects of the present disclosure are not limited thereto, the second display area AA2 may be disposed only in at least one portion of an outside of the first display area AA1. For example, depending on a requirement for the process and/or design, the second display area AA2 may be disposed in any one side, or the opposite two sides of the first display area AA1, or the second display area AA2 may be disposed in a portion having any length of an outside of the first display area AA1.

Each of the plurality of first pixels PX1 includes a plurality of first sub-pixels SP1. For example, the plurality of first sub-pixels SP1 may include a first red sub-pixel SPR1, a first green sub-pixel SPG1, a first blue sub-pixel SPB1, and a first white sub-pixel SPW1. One first pixel PX1 includes one first red sub-pixel SPR1, one first green sub-pixel SPG1, one first blue sub-pixel SPB1, and one first white sub-pixel SPW1 to be configured by a total of four first sub-pixels SP1.

Each of the plurality of second pixels PX2 includes a plurality of second sub-pixels SP2. For example, the plurality of second sub-pixels SP2 may include a second red sub-pixel SPR2, a second green sub-pixel SPG2, and a second blue sub-pixel SPB2. One second pixel PX2 includes two second red sub-pixels SPR2, one second green sub-pixel SPG2, and one second blue sub-pixel SPB2 to be configured by a total of four second sub-pixels SP2.

Referring to FIG. 5A, each of the plurality of first sub-pixels SP1 includes a first transistor T1, a second transistor T2, a third transistor T3, a storage capacitor Cst, and a first light emitting element 120.

Each of the first transistor T1, the second transistor T2, and the third transistor T3 included in the first sub-pixel SP1 includes a gate electrode, a source electrode, and a drain electrode. The first transistor T1, the second transistor T2, and the third transistor T3 may be P-type thin film transistors or N-type thin film transistors. For example, since in the P-type thin film transistor, holes flow from the source electrode to the drain electrode, the current may flow from the source electrode to the drain electrode. Since in the N-type thin film transistor, electrons flow from the source electrode to the drain electrode, the current may flow from the drain electrode to the source electrode. Hereinafter, the description will be made under the assumption that the first transistor T1, the second transistor T2, and the third transistor T3 are N-type thin film transistors in which the current flows from the drain electrode to the source electrode, but aspects of the present disclosure are not limited thereto.

The first transistor T1 includes a first active layer ACT1, a first gate electrode GE1, a first source electrode SE1, and a first drain electrode DE1. The first gate electrode GE1 is connected to the first node N1, the first source electrode SE1 is connected to the second node N2, and the first drain electrode DE1 is connected to the high potential power line VDD. The first transistor T1 controls a driving current to be supplied to the first light emitting element 120 in accordance with a gate-source voltage. Accordingly, the first transistor T1 may be referred to as a driving transistor.

The second transistor T2 includes a second active layer, a second gate electrode, a second source electrode, and a second drain electrode. The second gate electrode is connected to a scan line SL, the second source electrode is connected to the first node N1, and the second drain electrode is connected to a data line DL. The second transistor T2 may be turned on or off based on a scan signal from the scan line SL. When the second transistor T2 is turned on, a data voltage from the data line DL may be charged in the first node N1. The second transistor T2 may be referred to as a switching transistor.

The third transistor T3 includes a third active layer, a third gate electrode, a third source electrode, and a third drain electrode. The third gate electrode is connected to the scan line SL, the third source electrode is connected to the second node N2, and the third drain electrode is connected to the reference line RL. The third transistor T3 may be turned on or off based on a scan signal from the scan line SL. When the third transistor T3 is turned on, a reference voltage from the reference line RL may be transmitted to the storage capacitor Cst. The third transistor T3 may be referred to as a sensing transistor.

The storage capacitor Cst includes a plurality of capacitor electrodes. Some of the plurality of capacitor electrodes are electrically connected to the second node N2 and the remaining capacitor electrodes are electrically connected to the first node N1. The storage capacitor Cst stores a potential difference between the first gate electrode GE1 and the first source electrode SE1 of the first transistor T1 while the first light emitting element 120 emits light, so that a constant current may be supplied to the first light emitting element 120.

The first light emitting element 120 includes an anode 121 and a cathode 123. The anode 121 of the first light emitting element 120 is connected to the second node N2 and the cathode 123 is connected to a low potential power line VSS. The first light emitting element 120 is supplied with a driving current from the first transistor T1 to emit light.

Referring to FIG. 5B, each of the plurality of second sub-pixels SP2 includes a first transistor T1, a second transistor T2, a third transistor T3, a storage capacitor Cst, and a second light emitting element 130.

The second sub pixel SP2 may be configured with the same pixel circuit as the first sub-pixel SP1 except that the second light emitting element 130 is included instead of the first light emitting element 120. A connection relationship of the first transistor T1, the second transistor T2, the third transistor T3, and the storage capacitor Cst of the second sub-pixel SP2 is substantially the same as the first transistor T1, the second transistor T2, the third transistor T3, and the storage capacitor Cst of the first sub-pixel SP1.

The first electrode 134 of the second light emitting element 130 is connected to the second node N2 and the second electrode 135 is connected to a low potential power line VSS. The second light emitting element 130 is supplied with a driving current from the first transistor T1 to emit light.

In FIGS. 5A and 5B, it has been described that the sub pixel SP of the display apparatus 100 according to the exemplary aspect of the present disclosure has a 3T1C structure including three transistors and one storage capacitor Cst. However, the number and a connection relationship of the transistors and storage capacitors Cst included in one pixel circuit may vary in various ways depending on the design and are not limited thereto.

The first pixel PX1 and the second pixel PX2 disposed in the same row may be connected to the same scan line SL. Further, the first pixel PX1 and the second pixel PX2 disposed in the same column may be connected to the same data line DL. In addition, the first pixel PX1 and the second pixel PX2 disposed in the same column or same row may share a wiring line, such as a reference line RL or a high potential power line VDD.

The plurality of first sub-pixels SP1 which forms the first pixel PX1 may be disposed in two rows and two columns. For example, the first red sub-pixel SPR1 and the first blue sub-pixel SPB1 may be disposed on the same row and the first white sub-pixel SPW1 and the first green sub-pixel SPG1 may be disposed on the same row. Therefore, the first red sub-pixel SPR1 and the first white sub-pixel SPW1 which are disposed in different rows and the same column may be connected to the same data line DL. The first blue sub-pixel SPB1 and the first green sub-pixel SPG1 which are disposed in different rows and the same column may be connected to the same data line DL.

The plurality of second sub-pixels SP2 which forms the second pixel PX2 may be disposed in two rows and two columns. For example, one second red sub-pixel SPR2 of one pair of second red sub-pixels SPR2 may be disposed on the same row as the second blue sub-pixel SPB2 and the other second red sub-pixel SPR2 may be disposed on the same row as the second green sub-pixel SPG2. Therefore, one pair of second red sub-pixels SPR2 which are disposed in different rows and the same column may be connected to the same data line DL and the second blue sub-pixel SPB2 and the second green sub-pixel SPG2 may be connected to the same data line DL.

Even though in the drawing, it is illustrated that the plurality of first sub-pixels SP1 and the plurality of second sub-pixels SP2 are disposed in two rows and two columns, the plurality of first sub-pixels SP1 and the plurality of second sub-pixels SP2 may be disposed in various forms, such as being disposed in a stripe type or staggered with each other. Further, a type of the plurality of first sub-pixels SP1 which forms the first pixel PX1 and a placement order and the number of first red sub-pixels SPR1, first green sub-pixels SPG1, first blue sub-pixels SPB1, and first white sub-pixels SPW1 and a type of the plurality of second sub-pixels SP2 which forms the second pixel PX2 and a placement order and the number of second red sub-pixels SPR2, second green sub-pixels SPG2, and second blue sub-pixels SPB2 are illustrative. Therefore, a type, a placement order, and the number of sub-pixels SP which form each pixel PX are not limited thereto.

The first light emitting element 120 of the first pixel PX1 and the second light emitting element 130 of the second pixel PX2 have something in common: they are current-driven elements, but have different configurations and structures so that the data voltage may be applied in consideration of each characteristic. For example, the first light emitting element 120 is applied with a first data voltage and the second light emitting element 130 is applied with the second data voltage to independently control the first light emitting element 120 and the second light emitting element 130, respectively.

At this time, the first pixel PX1 and the second pixel PX2 disposed in the same column may be connected to the same data line DL. For example, some first pixel PX1 and some second pixel PX2 may share the same data line DL. In this case, a data voltage which is applied to the data line DL for one frame may be output in consideration of the first pixel PX1 and the second pixel PX2. For example, the second pixel PX2 may be connected to an uppermost end and a lowermost end of some data line DL and a plurality of first pixels PX1 may be connected between the second pixels PX2 at the uppermost end and the lowermost end. A second data voltage for driving the second pixel PX2 at the uppermost end, a plurality of first data voltages for driving the plurality of first pixels PX1, and a second data voltage for driving the second pixel PX2 at the lowermost end may be sequentially output to some data lines DL. A data line DL disposed at the outermost portion of the display panel PN may be connected only to the plurality of second pixels PX2. Therefore, a plurality of second data voltages for driving the plurality of second pixels PX2 may be sequentially output to the data line DL at the outermost side. Therefore, the first data voltage and the second data voltage may be selectively output in consideration of the order and the number of first pixels PX1 and second pixels PX2 connected to the data line DL.

Referring to FIG. 4 again, a gate driving area GIA in which the gate driver GD is disposed may be formed in the display area AA. For example, the gate driver GD may be mounted in the gate in display area manner in the display area AA. For example, the gate driving area GIA may be formed along a row direction and/or column direction in an area between the plurality of pixels PX. The gate driver GD formed in the gate driving area GIA between the plurality of pixels PX may apply a scan signal to the plurality of scan lines SL disposed in the display area AA. However, the gate driver GD and the gate driving area GIA may be formed on a rear surface of the display panel PN, rather than a front surface, or formed at the outside of the display area AA, but aspects of the present disclosure are not limited thereto.

A plurality of first pad electrodes PAD1 is disposed on the front surface of the display panel PN in which the plurality of pixels PX is formed. As described in FIG. 2A, the plurality of first pad electrodes PAD1 may transmit a signal from a driving component disposed on the rear surface of the display panel PN to a plurality of wiring lines disposed on the front surface of the display panel PN, through the side line SRL. For example, the plurality of first pad electrodes PAD1 may transmit a signal to the scan line SL, the data line DL, the reference line RL, the high potential power line VDD, the low potential power line VSS, and the like. Further, the plurality of first pad electrodes PAD1 may transmit a signal for driving the gate driver GD, for example, a clock signal, a gate low voltage, a gate high voltage, a start signal, and the like, to the gate driver GD of the gate driving area GIA.

Therefore, the plurality of first pad electrodes PAD1 may include a plurality of high potential power pads VDDP, a plurality of low potential power pads VSSP, a plurality of data pads DP, a plurality of reference pads RLP, and a plurality of gate pads GP. The plurality of high potential power pads VDDP and the plurality of low potential power pads VSSP may transmit a high potential power voltage and a low potential power voltage to the high potential power line VDD and the low potential power line VSS, respectively. The plurality of data pads DP may transmit a data voltage to the plurality of data lines DL and the plurality of reference pads RLP may transmit a reference voltage to the plurality of reference lines RL. Each of the plurality of gate pads GP may transmit a clock signal, a gate low voltage, a gate high voltage, a start signal, and the like to the gate driver GD of the gate driving area GIA.

At this time, wiring lines extending from the plurality of first pad electrodes PAD1 may extend to the display area AA. For example, the low potential power pad VSSP is disposed to be adjacent to the gate driving area GIA, but the low potential power line VSS extending from the low potential power pad VSSP may extend onto the display area AA, rather than the gate driving area GIA.

Even though in FIG. 4, it is illustrated that the gate pad GP is disposed at one side (or one portion) of the gate driving area GIA, the low potential power pad VSSP may be formed instead of the gate pad GP.

Referring to FIG. 6 together, the display panel PN of the display apparatus 100 according to the exemplary aspect of the present disclosure includes a substrate 110, a buffer layer 111, a gate insulating layer 112, an interlayer insulating layer 113, a passivation layer 114, a planarization layer 115, an adhesive layer 116, a bank 117, a first light emitting element 120, a second light emitting element 130, an encapsulation part 140, a low potential power line VSS, a plurality of reflection layer RFL, a first connection electrode CE1, a second connection electrode CE2, a dam DM, an electrostatic discharge circuit ESD, and a first pad electrode PAD1.

First, the substrate 110 is a component configured to support various components included in the display apparatus 100 and may be formed of an insulating material. For example, the substrate 110 may be formed of glass, resin, or the like. Further, the substrate 110 may be configured to include polymer or plastics or may be formed of a material having flexibility.

The buffer layer 111 is disposed on the substrate 110. The buffer layer 111 may reduce permeation of moisture or impurities through the substrate 110. For example, the buffer layer 111 may be configured by a single layer or a double layer of silicon oxide (SiOx) or silicon nitride (SiNx), but aspects of the present disclosure are not limited thereto. However, the buffer layer 111 may be omitted depending on a type of substrate 110 or a type of transistor, but aspects of the present disclosure are not limited thereto.

The first transistor T1 which is a driving transistor is disposed in each of the plurality of sub-pixels SP on the buffer layer 111. The first transistor T1 includes a first active layer ACT1, a first gate electrode GE1, a first source electrode SE1, and a first drain electrode DE1. The first transistor T1 corresponds to the first transistor T1 which has been described in FIGS. 5A and 5B.

The first active layer ACT1 is disposed on the buffer layer 111. The first active layer ACT1 may be formed of a semiconductor material such as an oxide semiconductor, amorphous silicon, low temperature polysilicon, or polysilicon, but aspects of the present disclosure are not limited thereto.

The gate insulating layer 112 is disposed on the first active layer ACT1. The gate insulating layer 112 is an insulating layer which insulates the first active layer ACT1 from the first gate electrode GE1 and may be configured by a single layer or a double layer of silicon oxide (SiOx) or silicon nitride (SiNx), but aspects of the present disclosure are not limited thereto.

The first gate electrode GE1 is disposed on the gate insulating layer 112. The first gate electrode GE1 may be configured by a conductive material, such as copper (Cu), aluminum (Al), molybdenum (Mo), nickel (Ni), titanium (Ti), and chrome (Cr), or an alloy thereof, but aspects of the present disclosure are not limited thereto.

The interlayer insulating layer 113 is disposed on the first gate electrode GE1. A contact hole is formed in the interlayer insulating layer 113 to allow each of the first source electrode SE1 and the first drain electrode DE1 to be connected to the first active layer ACT1. The interlayer insulating layer 113 is an insulating layer which protects components below the interlayer insulating layer 113 and may be configured by a single layer or a double layer of silicon oxide (SiOx) or silicon nitride (SiNx), but aspects of the present disclosure are not limited thereto.

A first source electrode SE1 and a first drain electrode DE1 which are electrically connected to the first active layer ACT1 are disposed on the interlayer insulating layer 113. The first source electrode SE1 and the first drain electrode DE1 may be configured by a conductive material, such as copper (Cu), aluminum (Al), molybdenum (Mo), nickel (Ni), titanium (Ti), chrome (Cr), or an alloy thereof, but aspects of the present disclosure are not limited thereto.

A plurality of low potential power lines VSS is disposed in an area between the plurality of sub-pixels SP on the interlayer insulating layer 113. The plurality of low potential power lines VSS may be electrically connected to the cathode 123 of the first light emitting element 120. The plurality of low potential power lines VSS may lower a resistance of the cathode 123 and minimize the luminance irregularity. A plurality of insulating layers and metal layers formed in a subsequent process may be disposed on the low potential power line VSS. To electrically connect the low potential power line VSS to the cathode 123, an undercut structure UC may be formed using a part of the plurality of insulating layers and metal layers during a process of forming a contact hole in the plurality of insulating layers and metal layers on the low potential power line VSS. For example, the undercut structure UC may be formed between the passivation layer 114 and the conductive layer UL formed by the same process as the anode 121. Referring to FIG. 4, the conductive layer UL which forms the undercut structure UC may be formed on the display area AA in which the low potential power line VSS is formed and the gate driving area GIA adjacent to the low potential power line VSS. For example, the conductive layer UL which forms the undercut structure UC may be formed on the low potential power line VSS at a boundary of the display area AA and the gate driving area GIA. In the undercut structure UC, the organic emission layer 122 of the first light emitting element 120 is disconnected and the cathode 123 is continuously formed so that the cathode 123 is in contact with a part of the low potential power line VSS exposed from the disconnected organic emission layer 122 to be electrically connected.

A second connection electrode CE2 to be described below is also electrically connected to a low potential power line VSS which is adjacent to the second pixel PX2, among the plurality of low potential power lines VSS to drive the second light emitting element 130.

The passivation layer 114 is disposed on the first transistor T1 and the plurality of low potential power lines VSS. The passivation layer 114 is an insulating layer which protects components below the passivation layer 114 and may be configured by a single layer or a double layer of silicon oxide (SiOx) or silicon nitride (SiNx), but aspects of the present disclosure are not limited thereto.

The planarization layer 115 is disposed on the passivation layer 114. The planarization layer 115 may planarize an upper portion of the substrate 110 on which the first transistor T1 is disposed. The planarization layer 115 may be configured by a single layer or a double layer, and for example, may be formed of photoresist or an acrylic organic material, but aspects of the present disclosure are not limited thereto.

The reflection layer RFL is disposed in each of the plurality of sub-pixels SP on the planarization layer 115. The plurality of reflection layers RFL is formed with a conductive material having an excellent reflective property to reflect light emitted from the plurality of light emitting diodes to an upper portion of the light emitting diode. For example, the reflection layer RFL may reflect light emitted from the second light emitting element 130, among the plurality of light emitting diodes to an upper portion of the substrate 110. In the first light emitting element 120, a reflective electrode is formed in the anode 121, but the second light emitting element 130 does not include a reflective electrode so that the reflection layer RFL is disposed below the second light emitting element 130 to emit light emitted from the second light emitting element 130 to the outside of the display apparatus 100.

Further, the reflection layer RFL may serve as a protection layer which protects a transistor in which an active layer is formed by an oxide semiconductor, among a plurality of transistors of the pixel circuit, from hydrogen. Oxygen in the oxide semiconductor is coupled to hydrogen to generate moisture and thus the characteristic of the oxide semiconductor may be changed. Therefore, the reflection layer RFL is formed to cover a pixel circuit and protects the plurality of transistors.

The reflection layer RFL may serve as an electrode which electrically connects the first transistor T1 and the plurality of light emitting diodes. For example, the reflection layer RFL of the first pixel PX1 may electrically connect the first transistor T1 and the anode 121 and the reflection layer RFL of the second pixel PX2 may electrically connect the first transistor T1 and the second connection electrode CE2 and the second electrode 135.

However, the reflection layer RFL may be used as another wiring line, rather than an electrode which connects the first light emitting element 120 and the second light emitting element 130 and the first transistor T1. For example, the reflection layer RFL may be used to connect to the low potential power line VSS or the high potential power line VDD, but aspects of the present disclosure are not limited thereto.

The adhesive layer 116 is disposed on the plurality of reflection layers RFL. The adhesive layer 116 is formed on the front surface of the substrate 110 to fix the second light emitting element 130 disposed on the adhesive layer 116. For example, the second light emitting element 130 is formed on a wafer and then transferred onto the display panel PN by a member, such as a donor. The adhesive layer 116 may fix the second light emitting element 130 which is transferred onto the display panel PN. For example, the adhesive layer 116 may be formed one of adhesive polymer, epoxy resist, UV resin, polyimide-based material, acrylate-based material, urethane-based-material, and polydimethylsiloxane (PDMS), but aspects of the present disclosure are not limited thereto.

The first light emitting element 120 is disposed in each of the plurality of first sub-pixels SP1 on the adhesive layer 116 and the second light emitting element 130 is disposed in each of the plurality of second sub-pixels SP2.

The first light emitting element 120 and the second light emitting element 130 are different types of elements. The first light emitting element 120 may be an organic light emitting diode (OLED) and the second light emitting element 130 may be a light emitting diode (LED) or a micro light emitting diode (LED) which is an inorganic light emitting diode. Both the first light emitting element 120 and the second light emitting element 130 are current light emitting diodes which are driven by a driving current, but may have different element structures and forming methods. For example, the first light emitting element 120 may be formed by depositing a material which forms the organic emission layer 122 and the cathode 123 on the front surface of the substrate 110. The second light emitting element 130 may be formed by growing a semiconductor layer on a wafer and patterning the semiconductor layer into a plurality of layers and the completed second light emitting element 130 is transferred onto the adhesive layer 116 of the display panel PN to form the second sub-pixel SP2.

First, in each of the plurality of first sub-pixels SP1, the first light emitting element 120 is disposed on the adhesive layer 116. The first light emitting element 120 includes an anode 121, an organic emission layer 122, and a cathode 123.

In each of the plurality of first sub-pixels SP1, the anode 121 is disposed on the adhesive layer 116. The anode 121 supplies holes to the organic emission layer 122 so that the anode may be formed of a conductive material having a high work function. For example, the anode 121 may be formed of a transparent conductive material such as indium tin oxide (ITO) and indium zinc oxide (IZO), but aspects of the present disclosure are not limited thereto. A reflective electrode which is formed of a metal material having an excellent reflection efficiency such as aluminum (Al) or silver (Ag), may be formed together below the anode 121 to reflect light emitted from the organic emission layer 122 from the anode 121 to be directed to the upper direction, for example, to the cathode 123.

The bank 117 is disposed on the anode 121. The bank 117 may include an opening through which at least a part of the anode 121 is exposed. The bank 117 is disposed at the boundary between the plurality of sub-pixels SP to reduce the color mixture of light of each of the plurality of sub-pixels SP. The bank 117 may be formed of an organic insulating material such as, polyimide, acryl, or benzocyclobutene (BCB) resin, but aspects of the present disclosure are not limited thereto.

The organic emission layer 122 is disposed on the front surface of the substrate 110, and on the bank 117. The organic emission layer 122 may be formed not only on the first sub-pixel SP1, but also on the second sub-pixel SP2. Therefore, the organic emission layer 122 may be formed as one layer over the plurality of sub-pixels SP. For example, the organic emission layers 122 of the plurality of sub-pixels SP are connected to each other to be integrally formed. The organic emission layer 122 may be configured as one organic emission layer 122 or may have a structure in which a plurality of organic emission layers 122 emitting different color light is laminated (or stacked). The organic emission layer 122 may further include an organic material layer such as a hole injection layer, a hole transport layer, an electron transport layer, an electron injection layer, and the like. The organic emission layer 122 is an emission layer which emits white light and light emitted from the organic emission layer 122 may be converted into various color light by means of a color conversion member, such as a color filter.

The cathode 123 is disposed on the front surface of the substrate 110 on the organic emission layer 122. The cathode 123 supplies electrons to the organic emission layer 122 so that the cathode may be formed of a conductive material having a low work function. The cathode 123 may be formed not only on the first sub-pixel SP1, but also on the second sub-pixel SP2. The cathode 123 may be formed as one layer over the plurality of sub-pixels SP. For example, the cathodes 123 disposed in the plurality of sub-pixels SP are connected to be integrally formed. For example, the cathode 123 may be formed of a transparent conductive material such as indium tin oxide (ITO) and indium zinc oxide (IZO) or ytterbium (Yb) alloy and may further include a metal doping layer, but aspects of the present disclosure are not limited thereto. The cathode 123 of the first light emitting element 120 is electrically connected to the low potential power line VSS to be supplied with a low potential power voltage.

The plurality of first light emitting elements 120 includes an organic emission layer 122 which emits white light so that a color conversion member which converts white color emitted from the plurality of first light emitting elements 120 into various color light may be further disposed. For example, a plurality of color filters which overlaps the first sub-pixel SP1 is disposed on the encapsulation part 140 to convert light emitted from the organic emission layer 122 into red light, green light, or blue light.

Next, referring to FIGS. 6 and 7 together, in each of the plurality of second sub-pixels SP2, the second light emitting element 130 is disposed on the adhesive layer 116. The plurality of second light emitting elements 130 may include second light emitting elements 130 which emit red light, green light, and blue light and implement various color light including white by a combination thereof. For example, the plurality of light emitting diodes may include a second red light emitting element 130R which emits red light, a second green light emitting diode 130G which emits green light, a second blue light emitting element 130B which emits blue light, and the like. The second red light emitting element 130R may be disposed in a second red sub-pixel SPR2, the second green light emitting element 130G may be disposed in a second green sub-pixel SPG2, and the second blue light emitting element 130B may be disposed in a second blue sub-pixel SPB2. Accordingly, all the first light emitting elements 120 emit white light, but the plurality of second light emitting elements 130 may be formed by a second red light emitting element 130R, a second green light emitting element 130G, and a second blue light emitting element 130B which emit different color lights.

The second light emitting element 130 includes a first semiconductor layer 131, an active layer 132, a second semiconductor layer 133, a first electrode 134, a second electrode 135, and a protection layer 136.

The first semiconductor layer 131 is disposed on the adhesive layer 116 and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n-type and p-type impurities into a material such as gallium nitride (GaN), indium aluminum phosphide (InAlP), and gallium arsenide (GaAs). The p-type impurity may be magnesium (Mg), zinc (Zn), beryllium (Be), and the like, and the n-type impurity may be silicon (Si), germanium (Ge), tin (Sn), and the like, but aspects of the present disclosure are not limited thereto.

The active layer 132 is disposed between the first semiconductor layer 131 and the second semiconductor layer 133. The active layer 132 is supplied with holes and electrons from the first semiconductor layer 131 and the second semiconductor layer 133 to emit light. The active layer 132 may be formed by a single layer or a multi-quantum well (MQW) structure, and for example, may be formed of indium gallium nitride (InGaN) or gallium nitride (GaN), but aspects of the present disclosure are not limited thereto.

The first electrode 134 is disposed on the first semiconductor layer 131. The first electrode 134 is an electrode which electrically connects the first transistor T1 which is a driving transistor and the first semiconductor layer 131. The first electrode 134 may be disposed on a top surface of the first semiconductor layer 131 which is exposed from the active layer 132 and the second semiconductor layer 133. The first electrode 134 may be configured by a conductive material, for example, a transparent conductive material, such as indium tin oxide (ITO) and indium zinc oxide (IZO) or an opaque conductive material, such as titanium (Ti), gold (Au), silver (Ag), and copper (Cu) or an alloy thereof, but aspects of the present disclosure are not limited thereto.

The second electrode 135 is disposed on the second semiconductor layer 133. The second electrode 135 may be disposed on an upper surface of the second semiconductor layer 133. The second electrode 135 is an electrode which electrically connects the low potential power line VSS and the second semiconductor layer 133. The second electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but aspects of the present disclosure are not limited thereto.

Next, the protection layer 136 which encloses (or surrounds) the first semiconductor layer 131, the active layer 132, the second semiconductor layer 133, the first electrode 134, and the second electrode 135 is disposed. The protection layer 136 is formed of an insulating material to protect the first semiconductor layer 131, the active layer 132, and the second semiconductor layer 133. In the protection layer 136, a contact hole which exposes the first electrode 134 and the second electrode 135 is formed to electrically connect a first connection electrode CE1 and a second connection electrode CE2 to the first electrode 134 and the second electrode 135.

Referring to FIG. 7, each of the second red light emitting element 130R, the second green light emitting element 130G, and the second blue light emitting element 130B of the plurality of second light emitting elements 130 has the same cross-sectional shape as illustrated in FIG. 6, but may have different planar shapes.

For example, the second red light emitting element 130R has a circular planar shape, the first electrode 134 has a ring shape disposed along a top surface of the first semiconductor layer 131, and the second electrode 135 may be formed with a circular shape. The second blue light emitting element 130B may have an overall oval-planar shape and the first electrode 134 may be disposed on both end portions of the first semiconductor layer 131 in a long axis direction. The second green light emitting element 130G may have an oval planar shape with a different width from that of the second blue light emitting element 130B. Further, in the second green light emitting element 130G, the first electrode 134 may be disposed on both end portions of the first semiconductor layer 131 in the long axis direction. However, a shape of the plurality of second light emitting elements 130 is illustrative, so that the second red light emitting element 130R, the second green light emitting element 130G, and the second blue light emitting element 130B may be configured in various shapes, such as an oval shape, a circular shape, or other shapes, respectively.

In each of the plurality of second sub-pixels SP2, the first connection electrode CE1 is disposed on the second light emitting element 130. The first connection electrodes CE1 is an electrode which electrically connects the second light emitting element 130 and the first transistor T1. The first connection electrode CE1 may be in contact with the first electrode 134 of the second light emitting element 130 which is exposed from the protection layer 136 and may be also connected to the reflection layer RFL through a contact hole formed in the adhesive layer 116. Accordingly, the first connection electrode CE1 may be electrically connected to the reflection layer RFL and the first source electrode SE1 and the first electrode 134 of the second light emitting element 130.

The first connection electrode CE1 may be formed on the same layer as the anode 121 of the first light emitting element 120 with the same material. The first connection electrode CE1 and the anode 121 may be formed by the same process. In this case, the second light emitting element 130 may be transferred onto the adhesive layer 116 first, and then a process of forming the first connection electrode CE1 and the anode 121 may be performed.

In each of the plurality of second sub-pixels SP2, the bank 117 is disposed to cover the second light emitting element 130 and the first connection electrode CE1. The bank 117 may cover a boundary between the plurality of sub-pixels SP and cover the second light emitting element 130 and the first connection electrode CE1 in the second sub-pixel SP2. The bank 117 may insulate the first connection electrode CE1 and the second connection electrode CE2 while protecting the second light emitting element 130. An upper portion of the second light emitting element 130, for example, the second electrode 135 is exposed from the bank 117 so that the second light emitting element 130 may be electrically connected to the second connection electrode CE2 which will be formed later.

In each of the plurality of second sub-pixels SP2, the second connection electrode CE2 is disposed on the bank 117. The second connection electrode CE2 is an electrode which electrically connects the second light emitting element 130 and the low potential power line VSS. The second connection electrode CE2 may be electrically connected to the second electrode 135 of the second light emitting element 130 exposed from the bank 117. Further, the second connection electrode CE2 may be also electrically connected to the low potential power line VSS.

Referring to FIG. 7, the first connection electrode CE1 disposed in each of the plurality of second sub-pixels SP2 may be individually disposed in each of the plurality of second sub-pixels SP2. The second connection electrodes CE2 which are disposed in each of the plurality of second sub-pixels SP2 to connect the low potential power line VSS and the second light emitting element 130 may be connected to each other. For example, the low potential power voltage of the low potential power line VSS is commonly applied to all the plurality of second light emitting elements 130 of the plurality of second sub-pixels SP2 so that one second connection electrode CE2 may be disposed in all the plurality of second sub-pixels SP2 which forms one second pixel PX2. Accordingly, in one second pixel PX2, a plurality of first connection electrodes CE1 and one second connection electrode CE2 may be disposed.

After sequentially performing a transferring process of the second light emitting element 130, a forming process of the first connection electrode CE1 and the anode 121, a forming process of the bank 117, and a forming process of the second connection electrode CE2, a forming process of the organic emission layer 122 and the cathode 123 may be performed. The organic emission layer 122 and the cathode 123 are formed by depositing materials which form the organic emission layer 122 and the cathode 123 on the front surface of the substrate 110 so that the organic emission layer 122 and the cathode 123 may be also formed in the second sub-pixel SP2.

The organic emission layer 122 may be formed on the second connection electrode CE2 and the bank 117 in the second sub pixel SP2 and the cathode 123 may be formed to cover all the organic emission layer 122. In the second sub-pixel SP2, the organic emission layer 122 disposed between the second connection electrode CE2 and the cathode 123 is in contact with both the second connection electrode CE2 and the cathode 123 to be electrically connected. However, both the second connection electrode CE2 and the cathode 123 are connected to the low potential power line VSS to have the same electrical potential so that the organic emission layer 122 formed on the second sub-pixel SP2 may not emit light. If different voltages are applied to the second connection electrode CE2 and the cathode 123, the organic emission layer 122 emits light so that the light emitted from the second light emitting element 130 may not be normally displayed. Therefore, a same voltage is applied to the second connection electrode CE2 and the cathode 123 so that a separate insulating layer which insulates the organic emission layer 122 and the second connection electrode CE2 in the second sub-pixel SP2 does not need to be formed. Further, the structure and the manufacturing process of the display apparatus 100 may be simplified.

Referring to FIGS. 4 and 6, one or more dams DM may be disposed between an edge of the display panel PN and the second sub-pixel SP2 in the second display area AA2. The dam DM may be formed to enclose the edge of the display panel PN. The dam DM may suppress or prevent the second encapsulation layer 142 of the encapsulation part 140 to be described below from overflowing to the outside of the display panel PN. Further, the dam DM disconnects the organic emission layer 122 and the cathode 123 of the first light emitting element 120 to reduce the permeation of moisture or oxygen into the first display area AA1 through the organic emission layer 122. Therefore, the dam DM may be formed to have a thick thickness with the undercut structure to disconnect the organic emission layer 122 and the cathode 123. For example, the dam DM includes a plurality of layers to have a thick thickness and the undercut structure may be formed between the first layer 114d and the second layer 115d.

The dam DM may be formed by patterning a plurality of insulating layers formed on the substrate 110. For example, the dam DM may be formed with a first layer 114d formed by patterning the passivation layer 114, a second layer 115d formed by patterning the planarization layer 115, a third layer 116d formed by patterning the adhesive layer 116, and a fourth layer 117d formed by patterning the bank 117. However, a configuration of the dam DM is illustrative, but aspects of the present disclosure are not limited thereto.

A first pad electrode PAD1 is disposed at the edge of the substrate 110. The first pad electrode PAD1 may be configured with a double layered structure. The first pad electrode PAD1 may be formed together with some conductive layers of the plurality of conductive layers formed on the substrate 110. For example, the first pad electrode PAD1 may be configured by a plurality of conductive layers formed with the same material on the same layer as at least some of configurations, such as the first gate electrode GE1, the first source electrode SE1, the first drain electrode DE1, the reflection layer RFL, and the anode 121.

The encapsulation part 140 is disposed on the plurality of first light emitting elements 120 and the plurality of second light emitting elements 130. The encapsulation part 140 seals the first light emitting element 120 which is an organic light emitting diode to protect the first light emitting element 120 from external moisture, oxygen, and shocks. The encapsulation part 140 may be formed with a multilayered structure in which an inorganic layer formed of an inorganic insulating material and an organic layer formed of an organic material are alternately laminated. For example, the encapsulation part 140 may include a first encapsulation layer 141 which is an inorganic layer, a second encapsulation layer 142 which is an organic layer, and a third encapsulation layer 143 which is an inorganic layer.

The first encapsulation layer 141 seals the display area AA to protect the light emitting diode from oxygen and moisture which permeates to the display area AA. The first encapsulation layer 141 may be formed of an inorganic material, such as silicon nitride (SiNx), silicon oxide (SiOx), and aluminum oxide (AlOx), but aspects of the present disclosure are not limited thereto.

The second encapsulation layer 142 is disposed on the first encapsulation layer 141. The second encapsulation layer 142 planarizes an upper portion of the first encapsulation layer 141 and is filled in cracks which may be generated in the first encapsulation layer 141. When foreign materials are disposed on the first encapsulation layer 141, the second encapsulation layer planarizes an upper portion of the foreign materials. The second encapsulation layer 142 may be formed of an organic material and for example, may use epoxy-based or acryl-based polymer, but aspects of the present disclosure are not limited thereto.

The third encapsulation layer 143 is disposed on the second encapsulation layer 142. The third encapsulation layer 143 is in contact with the first encapsulation layer 141 at the outer peripheral portion of the display apparatus 100 to seal the second encapsulation layer 142. Similar to the first encapsulation layer 141, the third encapsulation layer 143 may be formed of an inorganic material, such as silicon nitride SiNx, silicon oxide SiOx, and aluminum oxide AlOx, but aspects of the present disclosure are not limited thereto.

Referring to FIGS. 6 and 8 together, an electrostatic discharge circuit ESD is disposed in the second display area AA2. The electrostatic discharge circuit ESD is configured to discharge static electricity formed in the display apparatus 100. The electrostatic discharge circuit (ESD) discharges the static electricity to the outside of the display apparatus 100 to minimize the damage of the display apparatus 100. During the manufacturing process of the display apparatus 100, to implement the edge of the substrate 110 of the display panel PN according to a designed scheme, a process of cutting and processing the edge of the substrate 110 may be performed. During this process, the static electricity enters the display panel PN to cause the damage of the display panel PN. Therefore, the electrostatic discharge circuit ESD is disposed in the second display area AA2 adjacent to an edge of the display panel PN to discharge static electricity. For example, as illustrated in the drawing, the electrostatic discharge circuit ESD may be disposed below the planarization layer 115 in the second sub-pixel SP2 and also disposed below the dam DM.

The electrostatic discharge circuit ESD may be connected between any one of the plurality of wiring lines disposed on the display panel PN and a ground line. For example, the first node N1 of the electrostatic discharge circuit ESD is connected to a plurality of wiring lines, such as a data line DL, a scan line SL, or a reference line RL and the second node N2 may be connected to the ground line.

The electrostatic discharge circuit ESD includes an electrostatic discharge transistor ET, a first capacitor EC1, and a second capacitor EC2. A source electrode and a drain electrode of the electrostatic discharge transistor ET are connected to a first node N1 and a second node N2, respectively. The first capacitor EC1 is connected between the first node N1 and the gate electrode of the electrostatic discharge transistor ET and the second capacitor EC2 is connected between the second node N2 and the gate electrode of the electrostatic discharge transistor ET.

If an abnormally high voltage is applied to the wiring line connected to the first node N1 due to the static electricity, a voltage is applied from the first capacitor EC1 to the gate electrode of the electrostatic discharge transistor ET to turn on the electrostatic discharge transistor ET. Accordingly, the turned-on electrostatic discharge transistor ET may discharge the static electricity to the ground line. However, the configuration of the electrostatic discharge circuit ESD is illustrative, but aspects of the present disclosure are not limited thereto.

If the first light emitting element which is an organic light emitting diode is formed in the entire display panel, a bezel area of the display panel is necessary to minimize the moisture and oxygen permeating from the edge of the display panel to the display area. The first light emitting element is formed with a predetermined interval (or distance) from an edge of the display panel and a plurality of dams and trenches is disposed between the first light emitting element and an edge of the display panel, for example, in the bezel area of the display panel. However, when the display apparatus is designed to minimize the bezel area, the moisture permeation reliability is degraded so that the moisture and oxygen may easily permeate to the first light emitting element.

Accordingly, in the display apparatus 100 according to the exemplary aspect of the present disclosure, the first light emitting element 120 which is vulnerable to the moisture and oxygen is disposed in an inner area of the display panel PN and the second light emitting element 130 which has a high reliability to the moisture and oxygen is disposed at the outer peripheral area of the display panel PN. Thus, the moisture permeation reliability may be ensured while minimizing the bezel area. The dam DM and the trench which are disposed to reduce the permeation of the moisture and oxygen are disposed to the minimum, and instead, the plurality of second light emitting elements 130 which is inorganic light emitting diodes resistant to the moisture and oxygen may be disposed in the outer peripheral area of the display panel PN. The outer peripheral area of the display panel PN may serve as a display area AA in which the plurality of second light emitting elements 130 is disposed to display images. The plurality of second light emitting elements 130 serves as a dam DM to block moisture and oxygen permeating the first display area AA1. Accordingly, the second light emitting element 130 which is an inorganic light emitting diode is formed in an outer peripheral area of the display panel PN having a low moisture permeation reliability to protect the first light emitting element 120 which is an organic light emitting diode from the moisture and oxygen.

A display apparatus according to exemplary aspects of the present disclosure may also be described as follows.

A display apparatus according to aspects of the present disclosure may comprise a substrate including a first display area and a second display area surrounding the first display area, a plurality of first sub-pixels disposed at the first display area, a plurality of second sub-pixels disposed at the second display area, a first light emitting element disposed at each of the plurality of first sub-pixels, and a second light emitting element disposed at each of the plurality of second sub-pixels. The first light emitting element may include an organic light emitting diode and the second light emitting element may include an inorganic light emitting diode.

According to aspects of the present disclosure, the first light emitting element may include an anode, an organic emission layer disposed on the anode, and a cathode disposed on the organic emission layer.

According to aspects of the present disclosure, the second light emitting element may include a first semiconductor layer, an active layer disposed on the first semiconductor layer, a second semiconductor layer disposed on the active layer, a first electrode disposed on an upper surface of the first semiconductor layer, and a second electrode disposed on an upper surface of the second semiconductor layer.

According to aspects of the present disclosure, the display apparatus may further include a driving transistor disposed between the substrate and the first light emitting element and between the substrate and the second light emitting element, in each of the plurality of first sub-pixels and each of the plurality of second sub-pixels, and a power line electrically connected to the cathode of the first light emitting element and the second electrode of the second light emitting element.

According to aspects of the present disclosure, the display apparatus may further include a first connection electrode disposed at each of the plurality of second sub-pixels and electrically connected to the first electrode of the second light emitting element and the driving transistor, and a second connection electrode disposed at each of the plurality of second sub-pixels and electrically connected to the second electrode of the second light emitting element and the power line.

According to aspects of the present disclosure, the first connection electrode may be formed on the same layer with the same material as the anode.

According to aspects of the present disclosure, the organic emission layer and the cathode may be disposed on a front surface of the substrate and cover the second light emitting element and the second connection electrode of the plurality of second sub-pixels.

According to aspects of the present disclosure, in the plurality of second sub-pixels, the organic emission layer may be disposed between the second connection electrode and the cathode and a same voltage may be applied to the second connection electrode and the cathode from the power line.

According to aspects of the present disclosure, the display apparatus may further include a bank disposed between the plurality of first sub-pixels and between the plurality of second sub-pixels. In the plurality of first sub-pixels, the bank may be disposed between the anode and the organic emission layer. In the plurality of second sub-pixels, the bank may be disposed between the first connection electrode and the second connection electrode.

According to aspects of the present disclosure, the display apparatus may further include an encapsulation part disposed on the second connection electrode and the cathode. The encapsulation part may be configured to cover all the plurality of first sub-pixels and the plurality of second sub-pixels.

According to aspects of the present disclosure, the display apparatus may further include an adhesive layer disposed between the driving transistor and the first light emitting element and between the driving transistor and the second light emitting element. The anode of the first light emitting element and the first semiconductor layer of the second light emitting element may be in contact with an upper surface of the adhesive layer.

According to aspects of the present disclosure, the display apparatus may further include a planarization layer disposed between the driving transistor and the adhesive layer, and a reflection layer disposed at each of the plurality of first sub-pixels and the plurality of second sub-pixels between the planarization layer and the adhesive layer.

According to aspects of the present disclosure, the first light emitting element disposed at each of the plurality of first sub-pixels may emit white light.

According to aspects of the present disclosure, the second light emitting element may include a second red light emitting element which emits red light, a second green light emitting element which emits green light, and a second blue light emitting element which emits blue light.

According to aspects of the present disclosure, the display apparatus may further include a plurality of data lines which transmits a data voltage to the plurality of first sub-pixels and the plurality of second sub-pixels. Some of the plurality of data lines may be connected to both the plurality of first sub-pixels and the plurality of second sub-pixels and the others of the plurality of data lines may be connected only to the plurality of second sub-pixels.

A display apparatus according to aspects of the present disclosure may comprise a substrate including a first display area and a second display area disposed in at least one portion of an outside of the first display area, a plurality of first sub-pixels disposed at the first display area, a plurality of second sub-pixels disposed at the second display area, a first light emitting element disposed at each of the plurality of first sub-pixels, and a second light emitting element disposed at each of the plurality of second sub-pixels. The first light emitting element may include an organic light emitting diode and the second light emitting element may include an inorganic light emitting diode.

It will be apparent to those skilled in the art that various modifications and variations may be made in the display apparatus of the present disclosure without departing from the technical idea or scope of the present disclosure. Thus, it is intended that the present disclosure cover the modifications and variations of this disclosure provided that within the scope of the claims and their equivalents.

What is claimed is:

1. A display apparatus, comprising:
a substrate including a first display area and a second display area surrounding the first display area;
a plurality of first sub-pixels disposed at the first display area;
a plurality of second sub-pixels disposed at the second display area;
a first light emitting element disposed at each of the plurality of first sub-pixels; and
a second light emitting element disposed at each of the plurality of second sub-pixels,
wherein the first light emitting element includes an organic light emitting diode and the second light emitting element includes an inorganic light emitting diode.

2. The display apparatus of claim 1, wherein the first light emitting element includes:
an anode;
an organic emission layer disposed on the anode; and
a cathode disposed on the organic emission layer.

3. The display apparatus of claim 2, wherein the second light emitting element includes:
a first semiconductor layer;
an active layer disposed on the first semiconductor layer;
a second semiconductor layer disposed on the active layer;
a first electrode disposed on an upper surface of the first semiconductor layer; and
a second electrode disposed on an upper surface of the second semiconductor layer.

4. The display apparatus of claim 3, further comprising:
a driving transistor disposed between the substrate and the first light emitting element and between the substrate and the second light emitting element, in each of the plurality of first sub-pixels and each of the plurality of second sub-pixels; and
a power line electrically connected to the cathode of the first light emitting element and the second electrode of the second light emitting element.

5. The display apparatus of claim 4, further comprising:
a first connection electrode disposed at each of the plurality of second sub-pixels and electrically connected to the first electrode of the second light emitting element and the driving transistor; and
a second connection electrode disposed at each of the plurality of second sub-pixels and electrically connected to the second electrode of the second light emitting element and the power line.

6. The display apparatus of claim 5, wherein the first connection electrode is formed on a same layer with a same material as the anode.

7. The display apparatus of claim 5, wherein the organic emission layer and the cathode are disposed on a front surface of the substrate and cover the second light emitting element and the second connection electrode of the plurality of second sub-pixels.

8. The display apparatus of claim 7, wherein in the plurality of second sub-pixels, the organic emission layer is disposed between the second connection electrode and the cathode and a same voltage is applied to the second connection electrode and the cathode from the power line.

9. The display apparatus of claim 5, further comprising a bank disposed between the plurality of first sub-pixels and between the plurality of second sub-pixels,
wherein in the plurality of first sub-pixels, the bank is disposed between the anode and the organic emission layer, and
wherein in the plurality of second sub-pixels, the bank is disposed between the first connection electrode and the second connection electrode.

10. The display apparatus of claim 5, further comprising an encapsulation part disposed on the second connection electrode and the cathode,
wherein the encapsulation part is configured to cover all the plurality of first sub-pixels and the plurality of second sub-pixels.

11. The display apparatus of claim 4, further comprising an adhesive layer disposed between the driving transistor and the first light emitting element and between the driving transistor and the second light emitting element,
wherein the anode of the first light emitting element and the first semiconductor layer of the second light emitting element are in contact with an upper surface of the adhesive layer.

12. The display apparatus of claim 11, further comprising:
a planarization layer disposed between the driving transistor and the adhesive layer; and
a reflection layer disposed at each of the plurality of first sub-pixels and the plurality of second sub-pixels between the planarization layer and the adhesive layer.

13. The display apparatus of claim 1, wherein the first light emitting element disposed at each of the plurality of first sub-pixels emits white light.

14. The display apparatus of claim 13, wherein the second light emitting element includes:
a second red light emitting element which emits red light;
a second green light emitting element which emits green light; and
a second blue light emitting element which emits blue light.

15. The display apparatus of claim 1, further comprising a plurality of data lines which transmits a data voltage to the plurality of first sub-pixels and the plurality of second sub-pixels,
wherein some of the plurality of data lines are connected to both the plurality of first sub-pixels and the plurality of second sub-pixels and the others of the plurality of data lines are connected only to the plurality of second sub-pixels.
